(19) United States
(12) Patent Application Publication
(10) Pub. No.: US 2026/0093889 A1
(43) Pub. Date: Apr. 2, 2026

(54) POWER SWITCH PLACEMENT METHOD

(71) Applicant: GOOGLE LLC, Mountain View, CA (US)

(72) Inventors: Abhinav Ratna, Austin, TX (US); Kam-Tou Sio, Taipei (TW); Raja Kumar Martha, Pleasanton, CA (US)

(21) Appl. No.: 18/899,596

(22) Filed: Sep. 27, 2024

(51) Int. Cl. G06F 30/392

(52) U.S. Cl. CPC G06F 30/392

(57) ABSTRACT

A method of power switch placement and optimization in an integrated circuit is described. The method includes designating multiple sections in the integrated circuit. The sections are defined by a section width parallel to a first direction and a section length perpendicular to the first direction. For each section, a section type is determined based on a ratio of the section length to the section width belonging to a certain range of values. Each section has a corresponding power switch geometry specification determined in part by the section type. A power switch geometry specification is selected based on the section type, and the power switches are placed in each section according to the power switch geometry specification.

### BACKGROUND

This specification generally relates to power switch placement in semiconductor devices.

A power switch is used in semiconductor devices in a wide range of applications as part of a power grid structure. The power grid structure controls an electricity flow, including as routing the electricity flow and placing switches that turn the electricity flow on and off. As chip area keeps shrinking in modern semiconductor technology, the narrower metal pitch and smaller via size can become a performance bottleneck of semiconductor devices. Furthermore, smaller chip sizes can also cause an increase in resistance of the semiconductor device, thereby inducing thermal issues and reliability issues.

### SUMMARY

This specification describes power grid design systems, methods, and procedures for local optimization of power switch placement to alleviate the above-mentioned issues. In particular, power switch placement can reduce failure rates, improve reliability, and improve circuit performance.

In general, one innovative aspect of the subject matter described in this specification can be embodied in methods that include the actions of designating multiple sections in the integrated circuit. The integrated circuit includes multiple parallel rows, each row extending along a first longitudinal direction. Each section is defined by a section length and a section width. The section length is measured along the first longitudinal direction, and the section width is measured perpendicular to the first longitudinal direction. For each section, a section type is determined. The section type is defined by a ratio of the section length to the section width. Each section type corresponds to a particular ratio range, and each section type has a corresponding power switch geometry specification specific to that section type and different from each other section type. A power switch geometry specification is selected based on the section type, and the power switches are placed in each section according to the power switch geometry specification.

A first section type is defined by the ratio of the section length to the section width being greater than a first threshold value. A second section type is defined by the ratio of the section length to the section width being less than a second threshold value, wherein the second threshold value is less than the first threshold value. A third section type is defined by the ratio of the section length to the section width of between the first threshold value and the second threshold value.

Each corresponding power switch geometry specification comprises a first pitch constraint in the first longitudinal direction, a second pitch constraint perpendicular to the first longitudinal direction, a power switch length constraint in the first longitudinal direction, and a power switch width constraint perpendicular to the first longitudinal direction. The power switch length constraint is a first integral multiple of a polysilicon gate pitch. The power switch width constraint is a second integral multiple of a base cell length. In the first section type, the first integral multiple is within a first range. In the second section type, the first integral multiple is within a second range. In the third section type, the first integral multiple is within a third range.

In calculating the placement of the power switches, an initial metal resource based on an initial uniform placement of power switches across each section of the integrated circuit may be used as an initial condition of the optimization method. Then the metal resources may be calculated iteratively. Each iteration includes, for each section, determining the section type. Each iteration includes based on the section type, determining the pitches and the integral multiples and placing the power switches at updated locations. The pitches include a first pitch, a second pitch, a first integral multiple, and a second integral multiple and are all based on the corresponding power switch geometry specification of the section type of the section. The updated locations are based on either the initial uniform placement of power switches or a prior updated location based on the geometry specification determined from a prior iteration. After all the geometry specifications for all the sections have been determined, the metal resources of the integrated circuit are determined again using the updated placement of power switches across the integrated circuit. These iterations are repeated until a cessation condition is met.

The metal resource includes a power grid routing resource and a signal routing resource. The power grid routing resource includes a vertical power grid routing resource and a horizontal power grid routing resource. The signal routing resource includes a vertical signal routing resource and a horizontal signal routing resource. Determining the metal resource of the integrated circuit includes determining the metal resources for each section independently before determining the metal resource for the integrated circuit as a whole. Any sections which do not fall into one of the three types are further sub-divided into combinations of sections of the first section type, the second section type, and the third section type.

Other embodiments of this aspect include corresponding systems, apparatus, and computer programs, configured to perform the actions of the methods described above.

The subject matter described in this specification can be implemented in particular embodiments to realize one or more of the following advantages.

Some methods of power switch placement rely on a uniform spacing across a die which leads to several inefficiencies. Portions of the semiconductor go unutilized and metal routing resources do not properly balance the trade-off between power-related losses and performance. Certain regions of the integrated circuit experience higher congestion of metal wires which limits performance. There is an increased resistance-related voltage drop which may compromise signal integrity. Such uniform pitch placement fails to take into account differentiation amongst underlying circuit elements in different regions of the integrated circuit which result in power consumption variations in different regions. Regions with inherently higher power consumption require more power switches. In addition, non-uniform chip geometries or chip region geometries create additional power losses when a uniform placement of power switches is used.

The details of one or more implementations of the subject matter described in this specification are set forth in the accompanying drawings and the description below. Other potential features, aspects, and advantages of the subject matter will become apparent from the description, the drawings, and the claims.

### BRIEF DESCRIPTION OF THE DRAWINGS

FIG. 1 illustrates an example semiconductor device having a power grid in top-down view.

FIG. 2 illustrates the example semiconductor device of FIG. 1 in perspective view.

FIG. 3 illustrates the example semiconductor device of FIG. 1 in cross-section view.

FIG. 4 illustrates example section types with power switches.

FIG. 5 illustrates a close up of FIG. 4.

FIG. 6 illustrates an example placement of power switches in two sections.

FIG. 7 illustrates a flow chart of an example process for power switch placement.

Like reference numbers and designations in the various drawings indicate like elements.

### DETAILED DESCRIPTION

Placement of power switches in a power grid for directing electrical power to an integrated circuit or semiconductor device is essential to prolong device longevity, increase reliability, and avoid other problems of device over-heating while maintaining device operational capabilities including performing high-speed calculations.

The systems and methods described in this document define a power switch based on the length and width of the power switch. The fabricated polysilicon gates (or other underlying patterns) for the logic circuits processing the signal(s) in the integrated circuit mean that a rectilinear description is used. In addition to being delineated by the spacing of the polysilicon gates in one direction, the devices are also defined by the spacing between different rows of devices. The length and width of the power switch may thus be calculated based on these geometries. The metal resources for power distribution and signals are optimized and balanced according to an initial parameter set. The power switches are initially placed uniformly across the die with the power switch locations defined by X and Y coordinates along rows (e.g., perpendicular to the polysilicon gates) and columns (e.g., parallel to the polysilicon gates). A power simulation for the entire system is performed with timing and power consumption parameters determined. Then the power switch locations and sizes are adjusted and the metal resource routing is re-optimized taking into account the new power switch locations and sizes. The steps of adjusting power switch locations and sizes and then re-calculating the routing resource may be iterated until a desired condition or conditions are met. In an example, the integrated circuit may be simulated given the power switch locations, sizes, and the routing resource. If a timing parameter and a resistance parameter are both at or below particular values, then the iteration may stop. Alternatively, if a number of iterations exceeds a particular value, then the iteration may also stop.

These features and additional features are described in more detail below.

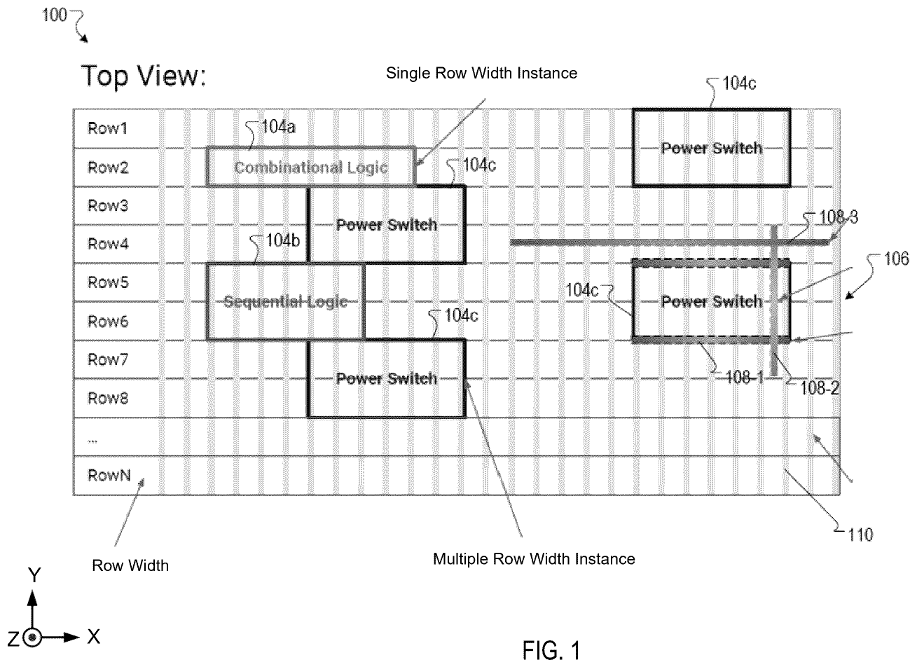

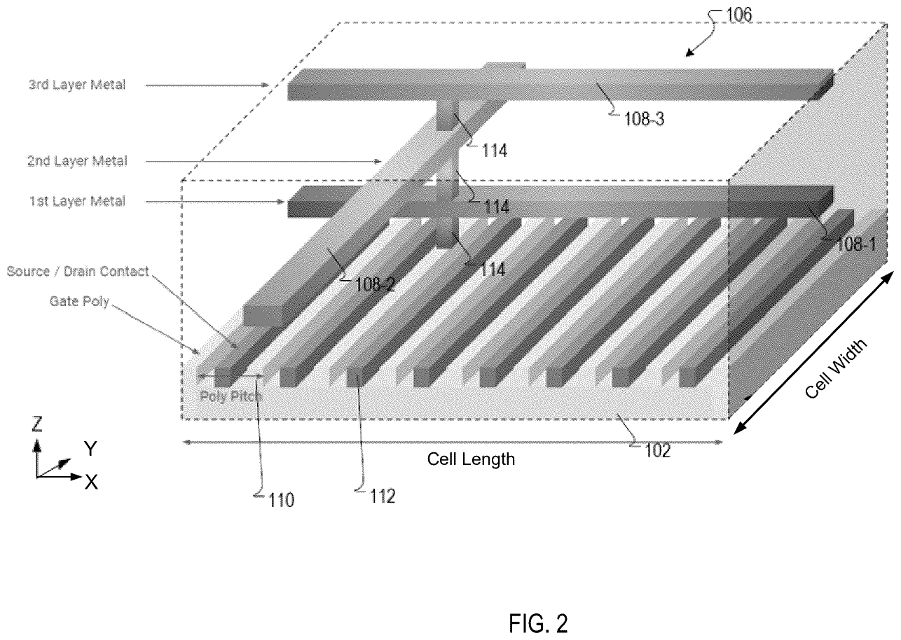

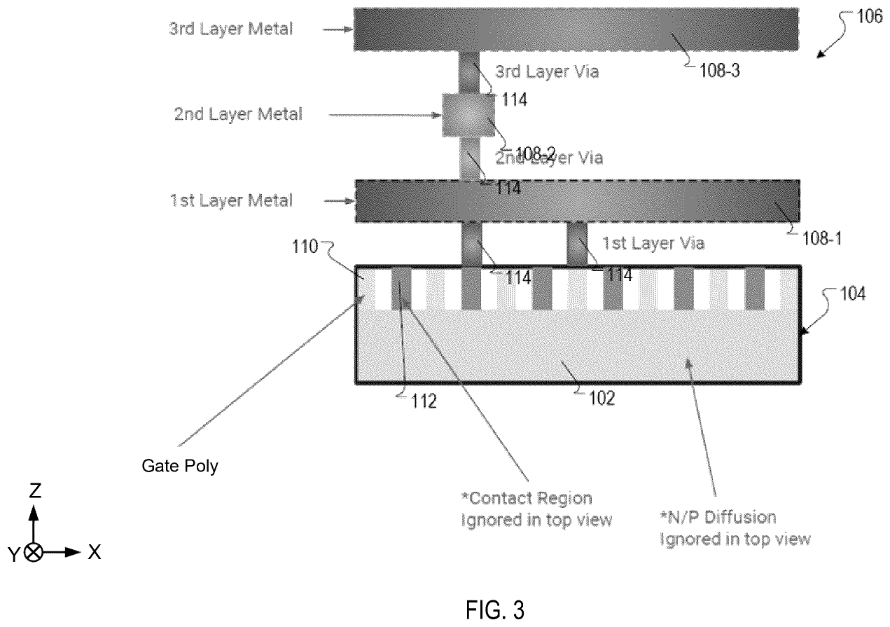

FIGS. 1-3 illustrate an example semiconductor device 100 having a power grid. FIG. 1 illustrates a top view of the semiconductor device 100. FIGS. 2-3 illustrate a perspective view and a side view of a cell of the semiconductor device 100, respectively. The X, Y, and Z axes (also referred to as X, Y, and Z directions) are included in FIGS. 1-3 to further illustrate the spatial relationship of various components in the semiconductor device 100. The X direction is a first longitudinal direction. The Y direction is a second longitudinal direction. The Z direction is a vertical direction. A substrate (e.g., substrate 102) of the semiconductor device can include two lateral surfaces extending laterally parallel to a horizontal plane (e.g., the X-Y plane): a top surface on the top side of the substrate on which a component of the semiconductor device can be formed, and a bottom surface on the bottom side opposite to the top side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

The semiconductor device 100 can have the substrate 102 (as shown in FIGS. 2-3) on which various circuits 104 (such as combinational logic 104a, sequential logic 104b, and power switches 104c as shown in FIG. 2) are formed. Each of these circuits 104 can be referred to as a cell and can include transistors formed using suitable techniques such as complementary metal-oxide-semiconductor (CMOS), field effect transistor (FET) techniques, fin field effect transistor (FinFET) techniques, and gate-all-around (GAA) transistors, etc.

In some implementations, as shown in FIG. 1, the semiconductor device 100 has a plurality of cell placement rows extending in a first longitudinal direction (e.g., the X direction). Each cell 104 may occupy one or more rows along a second longitudinal direction (e.g., the Y direction). The transistors of the cells 104 are arranged in an array and have gates 110 and source/drain contacts 112. The gates 110 and the contacts 112 can extend in a second longitudinal direction (e.g., the Y direction) perpendicular to the first longitudinal direction. In some instances, the gates 110 are made of a conductive material such as metal or polysilicon. In the example depicted in FIGS. 1-3, the polysilicon gates 110 extend in the second longitudinal direction (e.g., the Y direction). The contacts 112 also extend in the second longitudinal direction.

The power grid 106 of the semiconductor device 100 is coupled to the cells 104 and is configured to transmit power to the cells 104. For example, the power can be provided by an external power source coupled to the cells 104 by the power grid 106. The power grid 106 can include a plurality of metal layers 108 spaced along a vertical direction (e.g., the Z direction) perpendicular to both the first longitudinal direction (e.g., the X direction) and the second longitudinal direction (e.g., the Y direction). For example, as shown in FIGS. 1-3, the metal layers 108 can include a first metal layer 108-1 coupled to the cell 104, a second metal layer 108-2 being above and coupled to the first metal layer 108-1, and a third metal layer 108-3 being above and coupled to the second metal layer 108-2. The first metal layer 108-1 and the third metal layer 108-3 can extend in the first longitudinal direction. The second metal layer 108-2 can extend in the second longitudinal direction. The metal layers 108 are a horizontal metal resource.

The power grid 106 further includes vias 114 connecting adjacent metal layers at different heights and/or connecting a metal layer (e.g., the first metal layer 108-1) to the cell 104. As shown in FIGS. 2-3, the vias 114 extend in the Z direction. It is understood that while three metal layers are shown in FIGS. 1-3, this example is merely for illustration purpose. In practice, the semiconductor device 100 can have any suitable number of metal layers in the power grid 106. The vias 114 are a vertical metal resource.

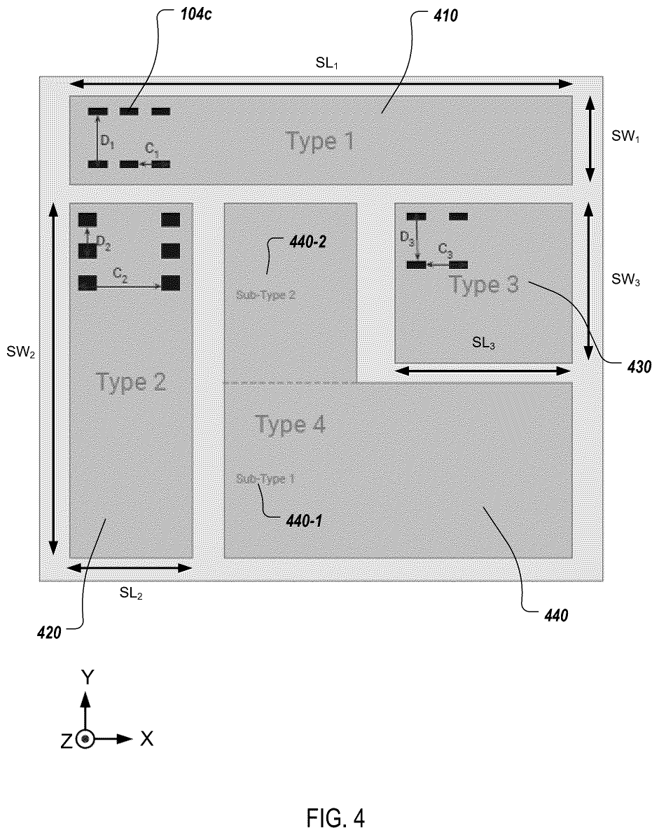

FIG. 4 illustrates an example layout of power switches for different section types. The sections cover the entire area of the semiconductor die or nearly the entire die. The integrated circuit includes a plurality of parallel rows, each row extending along a first longitudinal direction (e.g., the X direction). Each section has a section length along the first longitudinal direction and a section width along the second longitudinal direction. In the example illustrated, four sections are depicted. The different section types are defined based on a ratio of section length along the first longitudinal direction (e.g., the X direction) to a section width along the second longitudinal direction (e.g., the Y direction), i.e., the ratio which determines the section type is the ratio of the section length to the section width or SLᵢ/SWᵢ. For each section type there is a corresponding power switch geometry specification. As will be described in more detail below, each section type corresponds to a particular ratio range.

In the example implementation of FIG. 4, the first section type 410 has a section length SL₁ longer than a section width SW₁ so the ratio is larger than a first threshold value. Thus the ratio range is one in which the ratio is larger than the first threshold value. The second section type 420 has a section length SL₂ shorter than a section width SW₂ so the ratio is smaller than a second threshold value. Here, the second threshold value is less than the first threshold value. Thus the ratio range for the second section type is one in which the ratio is less than the second threshold value. The third section type 430 has a section length SL₃ comparable to a section width SW₃ so the ratio is between the first threshold value and the second threshold value, and thus the ratio range is between the second threshold value and the first threshold value.

In an example, the first threshold value is 1.5 and the second threshold value is 0.75. Thus, the first section type 410 has a section length greater than 1.5 times the section width; the second section type 420 has a section length which is less than 0.75 times the section width; and the third section type 430 has a section length between 0.75 times the section width and 1.5 times the section width. Other thresholds can also be used.

In addition to the three section types 410, 420, and 430, a fourth section type 440 may exist in the chip layout. The fourth section type 440 is a section which is not a regular-shaped rectangle but may form, for example, an L-shape. Other shapes are also possible for the fourth section type 440; however, they are constrained to be rectilinear in that they must be formable by combinations of the first through third section types. In the example depicted in FIG. 4, the example fourth section type 440 is rectilinear and can be sub-divided into sub-sections of the first through third section types. In this example, the fourth section type 440 is composed of a first sub-type 440-1 which is a subsection of the first section type 410 and a second sub-type 440-2 which is a subsection of the second section type 420. Similar decompositions of other fourth section types 440 are possible so long as any section of the fourth section type 440 can be made up of combinations of the first through third section types.

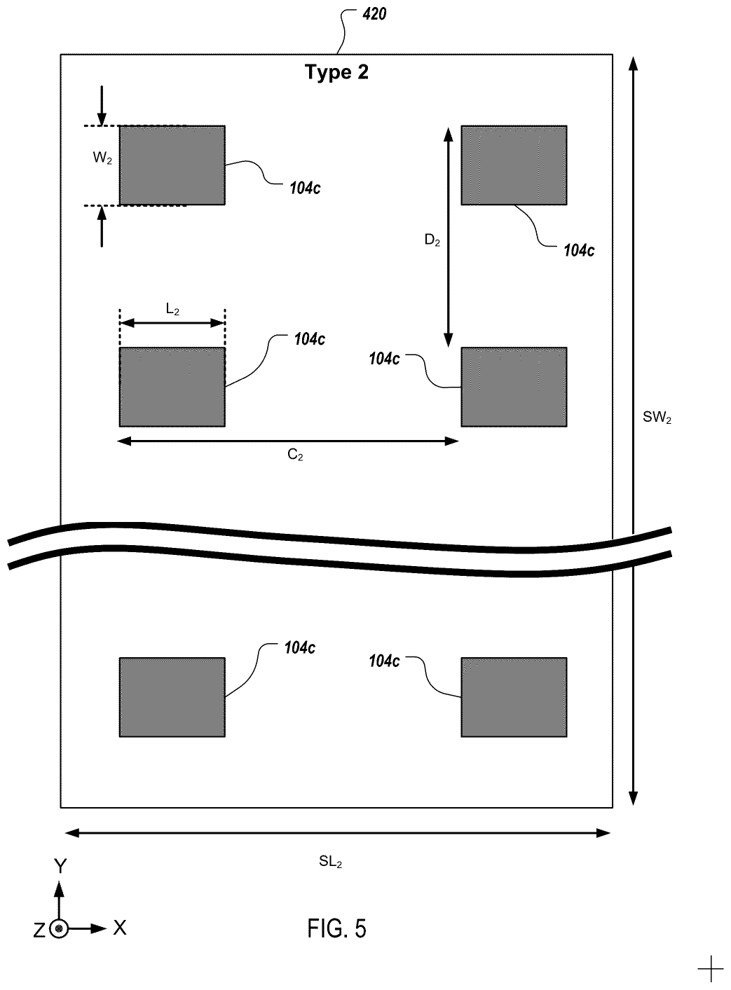

FIG. 5 illustrates a close-up of a portion of the second section type 420. For ease of explanation only six of the power switches 104c are illustrated. Power switches 104c are shown in a rectangular lattice across the section. Each power switch 104c has an associated length L₂ and an associated width W₂. The power switches 104c are spaced apart at a first pitch C₂ in the first longitudinal direction (e.g., the X direction) and a second pitch D₂ in the second longitudinal direction perpendicular to the first longitudinal direction. In this example, the subscripts denote the section type. The power switch geometry specification for each section includes the power switch length, the power switch width, the first pitch, and the second pitch and may be denoted in shorthand as {Lᵢ, Wᵢ, Cᵢ, and Dᵢ}. For each section, the power switch geometry specification determines a location {Cᵢ, Dᵢ} and a size {Lᵢ, Wᵢ} for each power switch within that section. By determining {Lᵢ, Wᵢ, Cᵢ, and Dᵢ} for each section, all the power switch locations of the entire integrated circuit may be determined. Each section has its own power switch geometry specification based on the section type and each section's power switch geometry specification is different from each other section's power switch geometry specification.

Each power switch geometry specification can be constrained. For example, the first pitch in the first longitudinal direction may be constrained to a first limited range. The second pitch in the second longitudinal direction may be constrained to a second limited range. The power switch length in the first longitudinal direction may be constrained to a third limited range. The power switch width in the second longitudinal direction may be constrained to a fourth limited range.

In some implementations, the values of {Lᵢ, Wᵢ, Cᵢ, and Dᵢ} can be constrained in various ways. For instance, the first pitch may be constrained to be only integral multiples of the pitch of the gate polysilicon (e.g., in the X direction) of the field effect transistors of the signal logic. Combinatorial logic circuits 104a, sequential logic circuits 104b, or other circuits may require constraints on the length and width of the power switches to use similar sized-transistors or similar-sized passive circuit components. In the example illustrated in FIGS. 1-3 the power switches 104c are constrained to have a power switch width in the second longitudinal direction no narrower than twice the width of a row (e.g., the width of the narrowest combinational logic circuit 104a) or no narrower than the width of some base cell. In examples, the power switch length may be constrained to a first range of multiples of the gate pitch for a first section type. An example first range is 30 to 60. In examples, the power switch length may be constrained with a second range of multiples of the gate polysilicon pitch for the second section type. An example second range is 10 to 40. In examples, the power switch length may be constrained with a third range of multiples of the gate polysilicon pitch for the third section type. An example third range is 20 to 50.

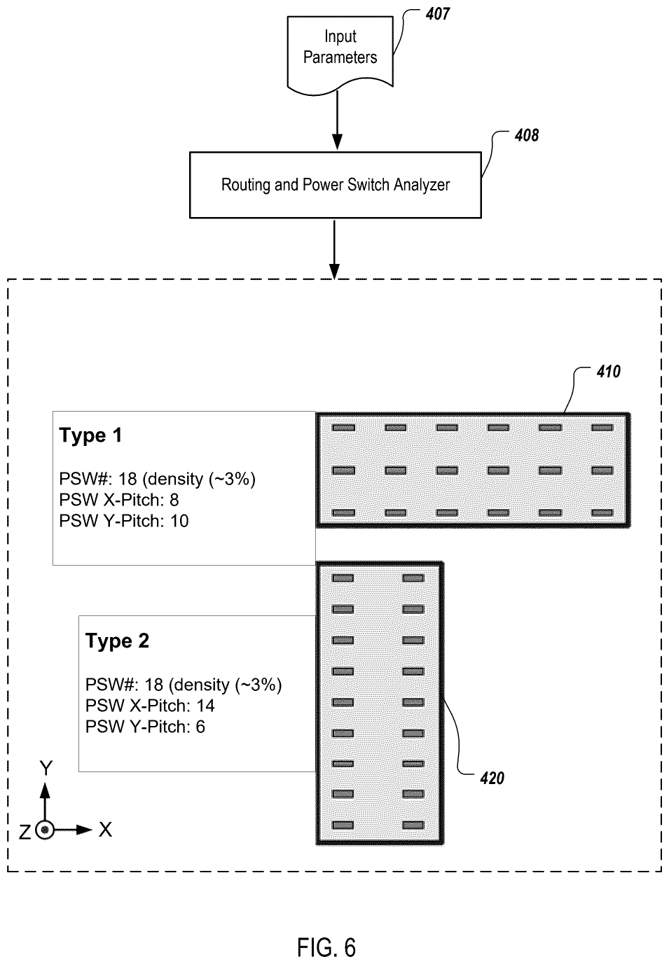

FIG. 6 illustrates examples of placement of power switches 104c for a first section type section 410 and a second section type section 420. In this example, a set of input parameters 407 are used to help determine the placement of power switches 104c. The input parameters may include initial metal resources and also an initial power switch geometry specification for each of the section types. These input parameters 407 are fed into a routing and power switch analyzer 408. The routing and power switch analyzer 408 can be implemented in a computer system programmed to perform various switch optimization routines described below. The routing and power switch analyzer 408 performs an optimization on the power switch geometry specification for each section and then performs an optimization for routing the metal resources. In this example, the first section type section 410 has three rows of power switches with a pitch in the first longitudinal direction of 8 and a pitch in the second longitudinal direction of 10. The second section type section 420 has two columns of power switches with a pitch in the first longitudinal direction of 14 and a pitch in the second longitudinal direction of 6. In each of these examples the power switches occupy approximately 3% of the entire area of the section. Other logic circuits, metal routing layers, or open spaces occupy the remainder of the chip surface.

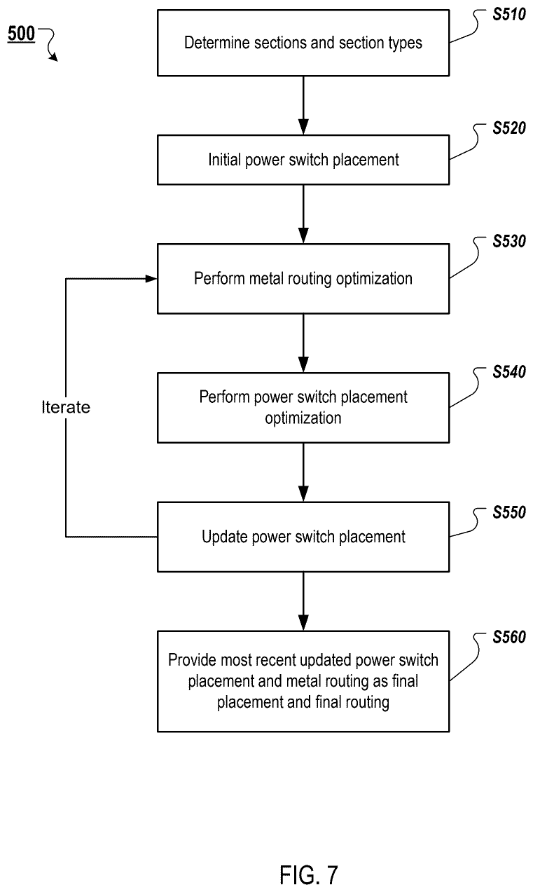

FIG. 7 illustrates an example method for the placement of the power switches across the entire integrated circuit. The method 500 starts with an operation (operation S510) of determining the various sections of the integrated circuit and categorizing them according to section type (first, second, third or fourth). Any fourth section type sections will include re-categorizing the fourth section type sections into sub-sections of the first through third section types.

After the entirety of the integrated circuit has been assigned to sections of the first through third section type (including the sub-sections of any fourth section type sections), the power switches are placed in an initial arrangement in each of the sections or sub-sections (operation S520). The initial arrangement of power switches includes determining the geometry specification of each of the sections. In an example, the initial the power switch placement is assumed to be uniform for each section with power switches of a single length and a single width within each section and also that a single first longitudinal direction pitch and a single second longitudinal direction pitch apply to each section. In different sections the power switch sizes may differ, but within each section all the power switches are the same size. Analogously in different sections, different first and second pitches may be used but within each section only a single first pitch and a single section pitch are used.

Once the power switches have been placed, including their locations and their sizes, a metal resource routing optimization is performed (operation S530). The first time this metal resource routing optimization occurs may result in an initial metal resource routing. The metal resource routing includes metal resource routing for the transmission of power and also metal resource routing for the logic signals. The metal resource routing includes vertical routing (e.g., vias connecting metal layers at different heights (Z direction)) and horizontal routing (e.g., metal along the first and second longitudinal directions). The metal resource routing optimization includes the limitation that the power metal wires must connect with the power switches and so the metal resource routing is influenced by the density and placement of the power switches.

After the metal resource routing has been optimized, the power switch placement is optimized given the just-optimized metal resource routing (operation S540). The power switch placement is subject to various constraints so that the pitches and sizes of the power switches are constrained. In some implementations, the corresponding power switch geometry specification comprises a first pitch constraint in the first longitudinal direction, a second pitch constraint perpendicular to the first longitudinal direction, a power switch length constraint in the first longitudinal direction, and a power switch width constraint perpendicular to the first longitudinal direction. For example, in some implementations, the power switch length constraint is a first integral multiple of a polysilicon gate pitch and the power switch width constraint is a second integral multiple of a base cell width. Thus, in the first section type, the first integral multiple is within a first range; in the second section type, the first integral multiple is within a second range; and in the third section type, the first integral multiple is within a third range.

Because each portion of the integrated circuit has already been assigned to a particular section, and all the sections are only of three types, the calculations required to optimize the power switch placement are greatly simplified. The power switches are defined for each section by only four parameters of the power switch geometry specification: power switch length (Lᵢ), power switch width (Wᵢ), the first (e.g., X-direction) pitch (Cᵢ), and the second (e.g., Y-direction) pitch (Dᵢ). These parameters may be varied or optimized according to various methods of optimization. For example, a grid approach to optimization may be used. In such an example, multiple possible configurations of the {Lᵢ, Wᵢ, Cᵢ, Dᵢ} for each section may be determined and each of these values are used to calculate an optimization parameter (or parameters) within the constrained range. An optimized optimization parameter(s) may be determined for each of the configurations. The highest value optimization parameter(s) may be selected and the associated configuration of {Lᵢ, Wᵢ, Cᵢ, Dᵢ} for that section may be selected. The different sections may be optimized together or individually. Analogously, other optimization methods may be used to determine an optimal power switch placement.

In an example, based on the section type, a first pitch and a second pitch {Cᵢ, Dᵢ} may be determined. The section length may be determined as a first integral multiple of a base cell and the section width may be determined as a second integral multiple of the gate polysilicon pitch. Thus by determining the first integral multiple and the second integral multiple, the power switch length and the power switch width {Lᵢ, Wᵢ} may be determined.

After the parameters for the locations of the power switches have been optimized, the power switches are placed at the new locations (operation S550). Then the process iterates back to the metal routing optimization (operation S530) using the new locations for the power switch placements. The iterations continue until a cessation condition is met. Example cessation conditions include exceeding a number of iterations, reaching a metric for simulated integrated circuit performance, reaching a metric for simulated power consumption, and the like.

After the iteration cessation condition has been met, the most recent updated power switch placements are used and a final metal routing is determined (operation S560). The most recent updated power switch placements are used as the final power switch placements and the final metal routing is used as well to complete the layout of the entire integrated circuit.

The metal resource includes both the power grid routing resource and the signal routing resource. When optimizing the signal routing resource, timing parameters for the combinatorial logic circuits 104a, the sequential logic circuits 104b, and other circuits may be taken into consideration. The power grid routing resource includes a vertical power grid routing resource and a horizontal power grid routing resource. The signal routing resource also includes a vertical signal routing resource and a horizontal signal routing resource. Determining the metal resources of the integrated circuit may include determining the metal resource for each section independently before determining the metal resource for the integrated circuit as a whole.

Embodiments of the subject matter and the operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented as one or more computer programs, i.e., one or more modules of computer program instructions, encoded on computer storage medium for execution by, or to control the operation of, data processing apparatus.

Apparatus to construct devices according to the processes described herein include semiconductor fabrication machine operable to perform the fabrication processes described herein. These include lithography machines, deposition tools, etchers, sputtering systems, dicing machines, linear guides, mask alignment tools, and other such machines and apparatus that can be configured to construct the devices realized the processes described herein. The methods, data processing apparatus and software described herein can be implemented to specify the above-described apparatus to perform functions and operations when constructing such semiconductor devices.

A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (e.g., multiple CDs, disks, or other storage devices).

The operations described in this specification can be implemented as operations performed by a data processing apparatus on data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., a FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing actions in accordance with instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's user device in response to requests received from the web browser.

Embodiments of the subject matter described in this specification can be implemented in a computing system that includes a back-end component, e.g., as a data server, or that includes a middleware component, e.g., an application server, or that includes a front-end component, e.g., a user computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network.

Examples of communication networks include a local area network (“LAN”) and a wide area network (“WAN”), an inter-network (e.g., the Internet), and peer-to-peer networks (e.g., ad hoc peer-to-peer networks).

The computing system can include users and servers. A user and server are generally remote from each other and typically interact through a communication network.

The relationship of user and server arises by virtue of computer programs running on the respective computers and having a user-server relationship to each other. In some embodiments, a server transmits data (e.g., an HTML page) to a user device (e.g., for purposes of displaying data to and receiving user input from a user interacting with the user device). Data generated at the user device (e.g., a result of the user interaction) can be received from the user device at the server.

While this specification contains many specific implementation details, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

What is claimed is:

1. A method of power switch placement in an integrated circuit comprising:
designating in the integrated circuit a plurality of sections, wherein:
the integrated circuit comprises a plurality of parallel rows, each row extending along a first longitudinal direction;
each section being defined by a section length and a section width,
wherein the section length is measured along the first longitudinal direction, and the section width is measured perpendicular to the first longitudinal direction;
for each section:
determining a section type, wherein the section type is defined by a ratio of the section length to the section width, each section type corresponding to a particular ratio range, and wherein each section type has a corresponding power switch geometry specification specific to that section type and different from each other section type;
selecting a power switch geometry specification for the section type of the section; and
placing power switches in the section according to the power switch geometry specification.

2. The method of claim 1, wherein:
a first section type is defined by the ratio of the section length to the section width being greater than a first threshold value;
a second section type is defined by the ratio of the section length to the section width being less than a second threshold value, wherein the second threshold value is less than the first threshold value; and
a third section type is defined by the ratio of the section length to the section width of between the first threshold value and the second threshold value.

3. The method of claim 2, wherein each corresponding power switch geometry specification comprises a first pitch constraint in the first longitudinal direction, a second pitch constraint perpendicular to the first longitudinal direction, a power switch length constraint in the first longitudinal direction, and a power switch width constraint perpendicular to the first longitudinal direction.

4. The method of claim 3, wherein:
the power switch length constraint is a first integral multiple of a polysilicon gate pitch;
the power switch width constraint is a second integral multiple of a base cell width;
in the first section type, the first integral multiple is within a first range;
in the second section type, the first integral multiple is within a second range; and
in the third section type, the first integral multiple is within a third range.

5. The method of claim 4, further comprising:
calculating initial metal resources based on an initial uniform placement of power switches across each section of the integrated circuit;
iteratively calculating metal resources of the integrated circuit, each iteration comprising:
for each section:
determining the section type of the section, and based on the section type:
determining a first pitch, a second pitch, a first integral multiple, and a second integral multiple based on the corresponding power switch geometry specification of the section type of the section; and
placing the power switches at updated locations, the updated locations based on either the initial uniform placement of power switches or a prior updated location determined from a prior iteration;
determining metal resources of the integrated circuit using the updated placement of power switches across the integrated circuit; and
repeating another iteration until a cessation condition is met.

6. The method of claim 5, wherein:
the metal resources comprise a power grid routing resource and a signal routing resource.

7. The method of claim 6, wherein:
the power grid routing resource comprises a vertical power grid routing resource and a horizontal power grid routing resource; and
the signal routing resource comprises a vertical signal routing resource and a horizontal signal routing resource.

8. The method of claim 6, wherein determining the metal resources of the integrated circuit comprises:
determining the metal resources for each section independently before determining the metal resources for the integrated circuit as a whole.

9. The method of claim 8, wherein any sections which do not fall into one of the first, second or third section types are further sub-divided into combinations of sections of the first section type, the second section type, and the third section type.

10. An apparatus, comprising:
a data processing apparatus; and
at least one memory coupled to the data processing apparatus and storing programming instructions for execution by the data processing apparatus to cause the data processing apparatus to perform operations comprising:
designating in an integrated circuit a plurality of sections, wherein:
the integrated circuit comprises a plurality of parallel rows, each row extending along a first longitudinal direction;
each section being defined by a section length and a section width,
wherein the section length is measured along the first longitudinal direction, and the section width is measured perpendicular to the first longitudinal direction;
for each section:
determining a section type, wherein the section type is defined by a ratio of the section length to the section width, each section type corresponding to a particular ratio range, and wherein each section type has a corresponding power switch geometry specification specific to that section type and different from each other section type;
selecting a power switch geometry specification for the section type of the section; and
specifying placing power switches in the section according to the power switch geometry specification.

11. The apparatus of claim 10, wherein:
a first section type is defined by the ratio of the section length to the section width being greater than a first threshold value;
a second section type is defined by the ratio of the section length to the section width being less than a second threshold value, wherein the second threshold value is less than the first threshold value; and
a third section type is defined by the ratio of the section length to the section width of between the first threshold value and the second threshold value.

12. The apparatus of claim 11, wherein each corresponding power switch geometry specification comprises a first pitch constraint in the first longitudinal direction, a second pitch constraint perpendicular to the first longitudinal direction, a power switch length constraint in the first longitudinal direction, and a power switch width constraint perpendicular to the first longitudinal direction.

13. The apparatus of claim 12, wherein:
the power switch length constraint is a first integral multiple of a polysilicon gate pitch;
the power switch width constraint is a second integral multiple of a base cell width;
in the first section type, the first integral multiple is within a first range;
in the second section type, the first integral multiple is within a second range; and
in the third section type, the first integral multiple is within a third range.

14. The apparatus of claim 13, the operations further comprising:
calculating initial metal resources based on an initial uniform placement of power switches across each section of the integrated circuit;
iteratively calculating metal resources of the integrated circuit, each iteration comprising:
for each section:
determining the section type of the section, and based on the section type:
determining a first pitch, a second pitch, a first integral multiple, and a second integral multiple based on the corresponding power switch geometry specification of the section type of the section; and
placing the power switches at updated locations, the updated locations based on either the initial uniform placement of power switches or a prior updated location determined from a prior iteration;
determining metal resources of the integrated circuit using the updated placement of power switches across the integrated circuit; and
repeating another iteration until a cessation condition is met.

15. The apparatus of claim 14, wherein:
the metal resources comprise a power grid routing resource and a signal routing resource.

16. The apparatus of claim 15, wherein:
the power grid routing resource comprises a vertical power grid routing resource and a horizontal power grid routing resource; and
the signal routing resource comprises a vertical signal routing resource and a horizontal signal routing resource.

17. The apparatus of claim 15, wherein determining the metal resources of the integrated circuit comprises:
determining the metal resources for each section independently before determining the metal resources for the integrated circuit as a whole.

18. The apparatus of claim 17, wherein any sections which do not fall into one of the first, second or third section types are further sub-divided into combinations of sections of the first section type, the second section type, and the third section type.
